(19) United States
(12) Patent Application Publication
(10) Pub. No.: US 2008/0230915 A1
(43) Pub. Date: Sep. 25, 2008

(54) SEMICONDUCTOR PACKAGE USING WIRES CONSISTING OF Ag OR Ag ALLOY

(75) Inventors: Jong Soo CHO, Seoul (KR); Jeong Tak MOON, Suwon-city (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: MK ELECTRON CO. LTD., Yongin-city (KR)

(21) Appl. No.: 12/051,078

(22) Filed: Mar. 19, 2008

(30) Foreign Application Priority Data
Mar. 23, 2007 (KR) 1020070028848

(51) Int. Cl. H01L 23/49

(52) U.S. Cl. 257/769; 257/E23.024

(57) ABSTRACT

A semiconductor package using Ag or Ag alloy wire which can maintain superior reliability against a noble metal and lower its manufacturing cost is provided. The semiconductor package comprises a semiconductor substrate. A semiconductor chip is attached to the package substrate and has one or more pads which comprise a noble metal. And one or more wires are bonded so as to electrically connect the one or more pads and the package substrate and comprise Ag or Ag alloy.

### CROSS-REFERENCE TO RELATED PATENT APPLICATION

This application claims the benefit of Korean Patent Application No. 10-2007-0028848, filed on Mar. 23, 2007, in the Korean Intellectual Property Office, the disclosure of which is incorporated herein in its entirety by reference.

### BACKGROUND OF THE INVENTION

1. Field of the Invention

The present invention relates to a semiconductor package, and more particularly, to a semiconductor package using a silver (Ag) or silver alloy wire.

2. Description of the Related Art

In a conventional semiconductor package, a pad of semiconductor chip is composed of aluminum. A package substrate and an aluminum pad are bonded using a gold (Au) wire. Gold has been widely used as a wire for bonding because the gold has high chemical stability and high electrical conductivity. However, in order to meet a demand for decreasing manufacturing cost in semiconductor industry and overcome a problem of increasing the manufacturing cost resulting from rising of gold value in recent years, a new wire to replace the gold wire is needed.

For example, although a gold-silver alloy wire has been used, because a composition of gold is still high, there are a limit in decreasing a manufacturing cost and a problem in view of reliability. There are Japanese Patent laid-open No. 1998-326803, 1999-67811, 1999-67812, 2000-150562 and so on as examples of study on gold-silver alloy wire.

In addition, in recent years, aluminum used as wiring metal in order to enhance the speed of the semiconductor chip has been replaced with copper. Accordingly, a material which consists the pad can be replaced with copper or other noble metal instead of aluminum. Accordingly, a wire which is capable of maintaining good bonding strength with the noble metal comprising copper is needed.

### SUMMARY OF THE INVENTION

The present invention provides a semiconductor package using a wire which can maintain superior reliability with a noble metal pad and can lower manufacturing cost.

According to an aspect of the present invention, there is provided a semiconductor package, comprising: a package substrate; a semiconductor chip which is attached to the package substrate and which has one or more pads, with the one or more pads comprising a noble metal; and one or more wires which are bonded so as to electrically connecting the one or more pads and the package substrate and which comprise Ag or Ag alloy.

In the present invention, the term “% by weight or weight %” refers to a ratio of weight of an alloy component or adding component to total weight of a wire in terms of “%”.

### BRIEF DESCRIPTION OF THE DRAWINGS

The above and other features and advantages of the present invention will become more apparent by describing in detail exemplary embodiments thereof with reference to the attached drawings in which:

FIG. 1 is a perspective view illustrating a semiconductor package according to an example of the present invention;

FIG. 2 is a graph showing an experimental result of bonding strength between wires and pads of the semiconductor packages according to a comparative example using an Al pad;

FIG. 3 is a photograph of a scanning electron microscope partly showing a semiconductor package before experiment of the bonding strength;

FIG. 4 and FIG. 5 are photographs of a scanning electron microscope partly showing the semiconductor package after experiment of the bonding strength;

FIG. 6 is a graph showing an experimental result of bonding strength between wires and pads of the semiconductor packages according to comparative example and experimental examples using a Pd pad; and

FIG. 7 and FIG. 8 are photographs of a scanning electron microscope partly showing the semiconductor package after experiment of the bonding strength.

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like numbers refer to like elements throughout the specification.

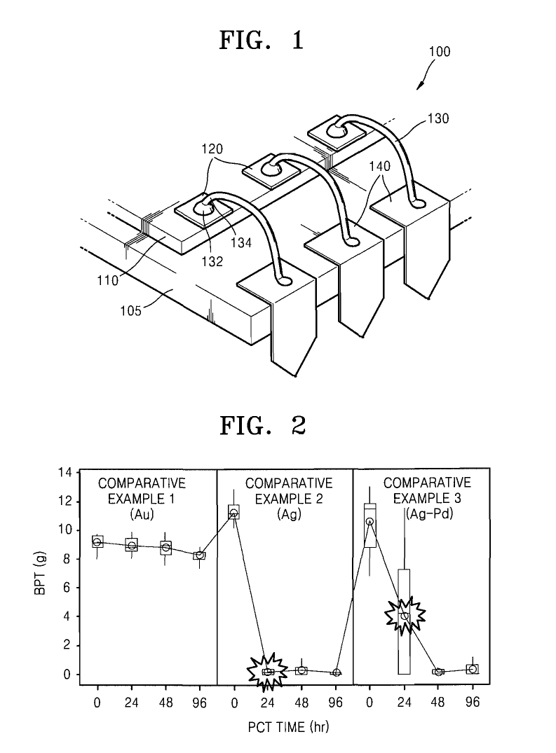

FIG. 1 is a perspective view illustrating a semiconductor package 100 according to an example of the present invention.

Referring to FIG. 1, a package substrate 105 may comprise one or more leads 140. For example, the package substrate 105 may be provided as a lead frame. The leads 140 can be provided for connecting of electronic products (not shown) and the semiconductor package 100. An arrangement of the leads 140 is shown for the purpose of illustration and can be variously varied according to the type of the semiconductor package 100.

In another example, the package substrate 105 can be provided as a printed circuit board. In such case, solder balls or a bumps (not shown) instead of the leads 140 can be used for electronically connecting the electronic product and the semiconductor package 100.

A semiconductor chip 110 can be attached on the package substrate 105. For example, the semiconductor chip 110 can comprise memory devices or logic devices. The scope of the present invention, however, is not limited to such example. The semiconductor chip 110 can comprise one or more pads 120.

The pads 120 can serve as outer terminals of the semiconductor chip 110. The pads 120 can be arranged at the edge of the semiconductor chip 110. The arrangement of the pads 120 can be varied depending on the semiconductor package 100. For example, the pads 120 can be arranged near the center of the semiconductor chip 110. The number of the pads 120 is shown for the purpose of illustration and the scope of the present invention is not limited to such example.

The pads 120 may be consisted of a noble metal instead of a conventional Al. In the embodiments of the present invention, the noble metal can refer to a metal which is chemically stable, i.e. oxidation and erosion can be hardly occurred. For example, the pad 120 can be consisted of at least one selected from a group consisted of Pd, Pt, Au, Ni and Cu. However, impurities can be inevitably included during manufacture of the pads 120.

The pads 120 and the package substrate 105 can be electrically connected by one or more wires 130. For example, wires 130 can be connected to the pads 120 and the leads 140 using a bonding technique. The wires 130 can comprise a ball portion 132 and a neck portion 134.

The wires 130 can be consisted of Ag or Ag alloy which essentially comprises Ag instead of a conventional Au. Ag has the highest electric conductivity among metals, for example the electric conductivity at least 30% higher than Au. In addition, since Ag is cheap as compared to Au, it can be contributed to reduce the cost of a material of the wires 130.

For example, Ag is sold in 1/30 through 1/50 cost of Au. In addition, since Ag has a mechanical property similar to Au, a conventional Au wire bonding process can be applied to an Ag wire bonding process as it is.

In this embodiment, Ag alloy can contain Ag of more than 95% by weight in order to maintain high electrical conductivity and enhance the effect of reducing the cost. Furthermore, Ag alloy can comprise Pd of less than 5% by weight in order to improve processability. In addition, other noble metal in addition to Pd as an alloy element can be added in less than 5% by weight.

Wires 130 which are consisted of Ag or Ag alloy can maintain superior bonding strength with the pads 120 which consists of the noble metal because a possibility that galvanic erosion occur between the noble metal and Ag or Ag alloy is low. Therefore, reliability in high humidity of the semiconductor package 100 can be improved.

The semiconductor package 100 can further comprise a molding material (not shown) enclosing the semiconductor chip 110 and the wires 130. For example, the molding material can comprise an epoxy molding compound (EMC).

The semiconductor package 100 according to the present embodiment can greatly lower a manufacturing cost using the wires 130 which consists of Ag or Ag alloy and maintain high reliability using the pads 120 which consist of the noble metal.

It will be described below comparison results of bonding strength of semiconductor packages according to comparison examples and experimental examples. The bonding strength is measured using a pressure cooker test (PCT) as one of high humidity reliability tests. The comparison examples shows typical semiconductor packages used pads which are composed of aluminum or wires which are composed of gold. The experimental example shows a semiconductor package using pads which are composed of a noble metal and wires which are composed silver or Ag alloy.

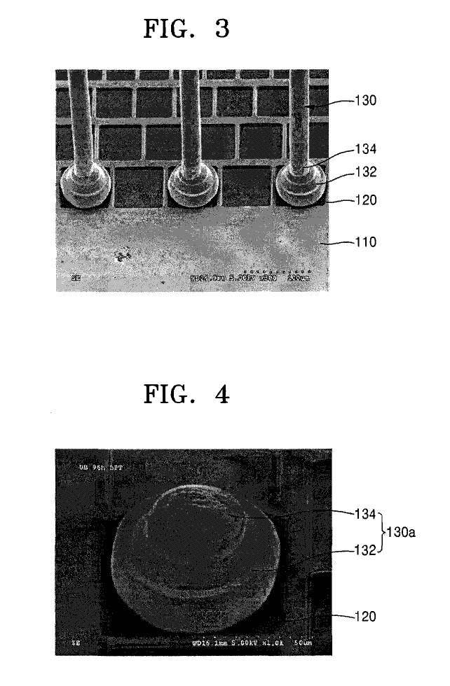

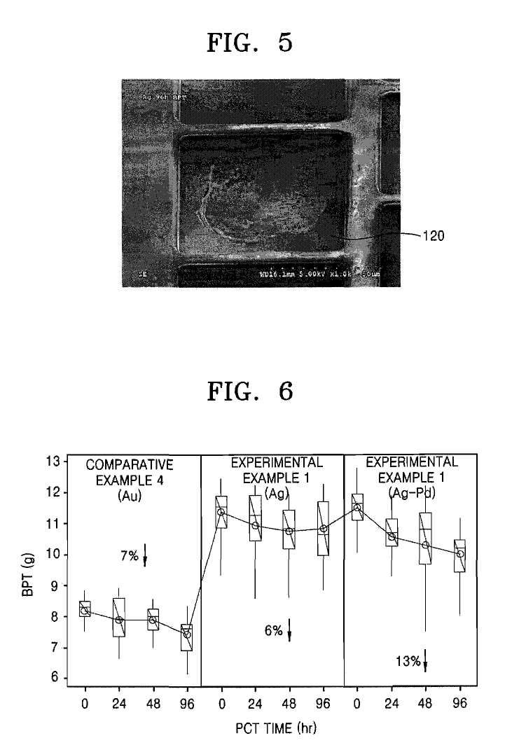

FIG. 2 is a graph showing an experimental result of bonding strength between wires and pads of the semiconductor packages according to a comparative example using an Al pad. FIG. 3 is a photograph of a scanning electron microscope partly showing a semiconductor package before experiment of the bonding strength; and FIG. 4 and FIG. 5 are photographs of a scanning electron microscope partly showing the semiconductor package after experiment of the bonding strength. In comparison examples 1 through 3, all pads are composed of aluminum (Al), and the wires are composed of gold (Au), silver (Ag) and silver-palladium (Ag—Pd), respectively.

Referring to FIG. 2, gold wires and aluminum pads in the comparison example 1 maintained their high bonding strength up to 96 hours. In the comparison example 2, BPT value showing the bonding strength between a silver wire and an aluminum pad is decreased up to 0 g within 24 hours. In the comparison 3, BPT value between a silver-palladium alloy wire and an aluminum pad is decreased up to 0 within 48 hours. Therefore, it will be appreciated that the aluminum pad and the gold wire maintained high reliability in view of the bonding strength, while the aluminum pad and silver or silver alloy wire have very poor reliability in view of the bonding strength.

Referring to FIG. 3, it will be appreciated that before experimenting the bonding strength the wires 130 are stably bonded to the pad 120. A ball portion 132 is directly attached to the pad 120, and a neck portion 132 is extended from the ball portion. In this case, the wires 130 typically show any of comparison examples 1 though 3.

Referring to FIG. 4, in case of comparison example 1, it will be appreciated that destroy occurred at a neck portion of wire 130a during the experiment of the bonding strength. It will be appreciated that until the wire 130a is destroyed, the ball portion 132 maintains its adhesive strength to the pad 120.

Referring to FIG. 5, in cases of comparison example 2 and 3, the wire is detached from the pad 120 during the experiment of the bonding strength. In other words, it will be appreciated that the ball portion is detached from the pad 120 before the neck portion is destroyed. This result is analyzed that galvanic corrosion is occurred in an interface between the pad 120 and the wire. Therefore, it will be appreciated that Ag or Ag alloy wire is difficult to use in bonding to aluminum pad.

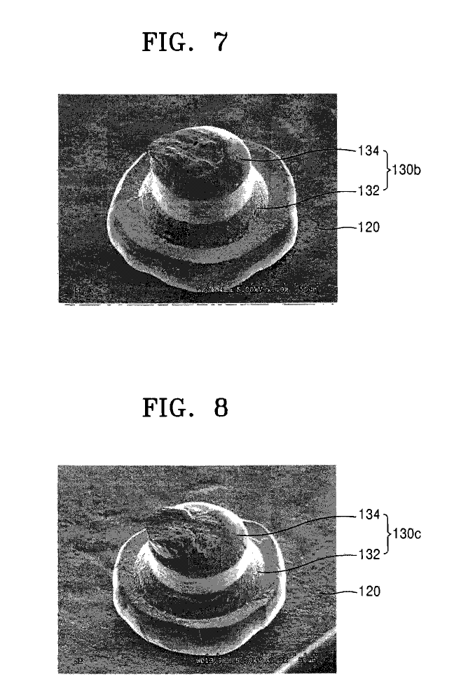

FIG. 6 is a graph showing an experimental result of bonding strength between wires and pads of the semiconductor packages according to comparative example and experimental examples using a Pd pad. FIG. 7 and FIG. 8 are photographs of a scanning electron microscope partly showing the semiconductor package after experiment of the bonding strength. In comparative example 4 and the experimental examples 1 and 2, all pads are composed of palladium. The wires in the comparative example 4 are composed of gold, the wires in the experimental example are composed of silver, and the wires in the experimental 2 are composed of silver-palladium alloy.

Referring to FIG. 6, all of the comparative example 4, the experimental example 1 and the experimental example 2 showed relatively superior bonding strength. After PCT of 96 hours, the BPT value showing the bonding strength are decreased by about 7% in case of the comparative example 4 and are decreased by about 6% in case of the experimental example 1 and are decreased by about 13% in case of the experimental example 2. The results of such experimental examples 1 and 2 are significantly contrasted with the results of the comparative example 2 and 3 as described above. Accordingly, it will be appreciated that the silver or silver-palladium alloy wire has superior bonding strength with the palladium pad.

Referring to FIG. 7, in case of the comparative example 4, it will be appreciated that destroy is occurred at a neck portion 134 of the wire 130b during the test of a bonding strength. It will be appreciated that a ball portion 132 maintains its adhesive strength to the pad 120 until the wire 130b is destroyed.

Referring to FIG. 8, in cases of experimental examples 1 and 2, it will be appreciated that destroy is occurred at a neck portion 134 of the wire 130c during the bonding strength test. It will be appreciated that the ball portion 132 maintains its adhesive strength to the pad 120 until the wire 130c is destroyed.

Although the pad 120 is composed of palladium, for example, in the experimental examples 1 and 2 as described above, other noble metal such as platinum (Pt), gold (Au), nickel (Ni) or copper (Cu) can also obtain the same effects.

The semiconductor package according to the present invention can save the manufacturing cost and lower the electrical conductivity using silver or silver alloy wire instead of a conventional gold wire.

In addition, the semiconductor package according to present invention can obtain high bonding strength to silver or silver alloy wire using the noble metal pad, and thus have high reliability.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package, comprising:
a package substrate;
a semiconductor chip which is attached to the package substrate and which has one or more pads, with the one or more pads comprising a noble metal; and
one or more wires which are bonded so as to electrically connect the one or more pads and the package substrate and which comprise Ag or Ag alloy.

2. The semiconductor package of claim 1, wherein the one or more pads comprise at least one selected from a group consisting of Pd, Pt, Au, Ni and Cu.

3. The semiconductor package of claim 1, wherein the one or more wires comprise Ag of more than 95% by weight.

4. The semiconductor package of claim 3, wherein the one or more wires further comprise Pd of less than 5% by weight.
